(19) United States
(12) Patent Application Publication
(10) Pub. No.: US 2024/0164221 A1
(43) Pub. Date: May 16, 2024

(54) METHOD FOR TREATING TANTALUM METAL THIN FILM, QUANTUM DEVICE, AND QUANTUM CHIP

(71) Applicant: Alibaba Damo (Hangzhou) Technology Co., Ltd., Hangzhou, Zhejiang (CN)

(72) Inventors: Hao DENG, Hangzhou (CN); Xiaohang ZHANG, Hangzhou, Zhejiang (CN)

(21) Appl. No.: 18/486,548

(22) Filed: Oct. 13, 2023

(30) Foreign Application Priority Data
Nov. 11, 2022 (CN) 202211408734.4

(51) Int. Cl. H10N 60/01; G06N 10/40; H10N 60/85

(52) U.S. Cl. CPC H10N 60/01; G06N 10/40; H10N 60/85

(57) ABSTRACT

The present disclosure discloses a method for treating a tantalum metal thin film, a quantum device, and a quantum chip. The method includes: preparing an initial tantalum metal thin film; and increasing, after cooling the initial tantalum metal thin film to a predetermined extremely low temperature, the temperature from the predetermined extremely low temperature to normal temperature to obtain a target tantalum metal thin film. The present disclosure solves the technical problem in the related technology: a post-treatment technology for a tantalum metal thin film after preparation of the tantalum metal thin film has a limited positive effect on reducing the energy dissipation of a tantalum-based superconducting quantum device.

### CROSS REFERENCE TO RELATED APPLICATIONS

The disclosure claims the benefits of priority to Chinese Application No. 202211408734.4, filed on 11 Nov. 2022, which is incorporated herein by reference in its entirety.

### TECHNICAL FIELD

The present disclosure relates to the field of quantum computation, in particular to a method for treating a tantalum metal thin film, a quantum device, and a quantum chip.

### BACKGROUND

In conventional technologies, preparing a tantalum metal thin film generally follows a common method for preparing a metal thin film in the semiconductor industry, such as sputtering. After corresponding post-treatment is performed on a prepared tantalum metal thin film, a superconducting quantum device is then prepared. Conventional post-treatment methods include chemical cleaning, ion milling, high-temperature annealing, and the like. However, the post-treatment methods listed above are basically inherited from methods for post-treating a thin film material in the traditional semiconductor industry, and have no significant positive effect on improving the performance of energy dissipation of a tantalum-based superconducting quantum device. Accordingly, for the tantalum metal thin film after preparation of a tantalum metal thin film, post-treatment technology has a limited positive effect on reducing the energy dissipation of a tantalum-based superconducting quantum device.

### SUMMARY

Embodiments of the present disclosure provide a method for treating a tantalum metal thin film, a quantum device, and a quantum chip, so as to at least solve the technical problem in the related technology: a post-treatment technology for a tantalum metal thin film after preparation of the tantalum metal thin film has a limited positive effect on reducing the energy dissipation of a tantalum-based superconducting quantum device.

According to an aspect of the embodiments of the present disclosure, a method for treating a tantalum metal thin film is provided, including: preparing an initial tantalum metal thin film; and increasing, after cooling the initial tantalum metal thin film to a predetermined extremely low temperature, the temperature from the predetermined extremely low temperature to normal temperature to obtain a target tantalum metal thin film.

Optionally, the predetermined extremely low temperature is located within the following temperature range: 0 mK to 77 K.

Optionally, the predetermined extremely low temperature is located within the following temperature range: 0 mK to 120 K.

Optionally, the predetermined extremely low temperature is 10 mK.

Optionally, the normal temperature is a temperature greater than zero degrees Celsius.

Optionally, the increasing, after cooling the initial tantalum metal thin film to a predetermined extremely low temperature, the temperature from the predetermined extremely low temperature to normal temperature to obtain a target tantalum metal thin film includes: increasing, after cooling the initial tantalum metal thin film to the predetermined extremely low temperature within a first predetermined duration, the temperature from the predetermined extremely low temperature to normal temperature within a second predetermined duration to obtain the target tantalum metal thin film.

Optionally, the first predetermined duration is counted in days, and the second predetermined duration is counted in days.

Optionally, the first predetermined duration is counted in hours, and the second predetermined duration is counted in hours.

Optionally, after the increasing, after cooling the initial tantalum metal thin film to a predetermined extremely low temperature, the temperature from the predetermined extremely low temperature to normal temperature to obtain a target tantalum metal thin film, the method further includes: preparing a tantalum-based superconducting quantum device on the basis of the target tantalum metal thin film.

Optionally, the increasing, after cooling the initial tantalum metal thin film to a predetermined extremely low temperature, the temperature from the predetermined extremely low temperature to normal temperature to obtain a target tantalum metal thin film includes: preparing, on the basis of the initial tantalum metal thin film, a tantalum metal base layer used for preparing a tantalum-based superconducting quantum device; and increasing, after cooling the tantalum metal base layer to the predetermined extremely low temperature, the temperature from the predetermined extremely low temperature to the normal temperature to obtain a target tantalum metal base layer formed by the target tantalum metal thin film.

Optionally, the tantalum-based superconducting quantum device is Fluxonium quantum bit.

According to another aspect of the present disclosure, a quantum device is provided. The quantum device is a tantalum-based superconducting quantum device; the tantalum-based superconducting quantum device includes a tantalum metal base layer; the tantalum metal base layer includes a target tantalum metal thin film; and the target tantalum metal thin film is obtained by using any method for treating a tantalum metal thin film described above.

According to yet another aspect of the present disclosure, a quantum chip is provided, which includes any of the above-mentioned quantum device.

According to still another aspect of the present disclosure, a quantum memory is provided, which includes any of the above-mentioned quantum device.

According to still yet another aspect of the present disclosure, a quantum computer is provided, which includes any of the above-mentioned quantum chip and/or the above-mentioned quantum memory.

In the embodiments of the present disclosure, after the initial tantalum metal thin film is cooled to the predetermined extremely low temperature, the temperature is increased from the predetermined extremely low temperature to the normal temperature to obtain the target tantalum metal thin film, which means that after the tantalum metal thin film is cooled to the extremely low temperature, the post-treatment method for increasing the temperature of the tantalum metal thin film to the normal temperature is used to obtain the tantalum metal thin film that can be subsequently used for preparing the desired superconducting quantum device, so that with respect to a post-treatment method for a thin film material in the traditional semiconductor industry, the energy dissipation of the superconducting quantum device obtained by the above post-treatment is significantly improved. Thus, the technical problem in the related technology that a post-treatment technology for the tantalum metal thin film after preparation of the tantalum metal thin film has a limited positive effect on reducing the energy dissipation of a tantalum-based superconducting quantum device is solved.

### BRIEF DESCRIPTION OF THE DRAWINGS

The accompanying drawings described herein are intended to provide further understanding of the present disclosure and constitute a part of this application. Exemplary embodiments of the present disclosure and the description thereof are used for explaining the present disclosure rather than constituting the improper limitation to the present disclosure. In the accompanying drawings:

FIG. 1 is a flowchart of an example method for treating a tantalum metal thin film according to some embodiments of the present disclosure;

FIG. 2 is a flowchart of an example method for treating a tantalum metal thin film according to some embodiments of the present disclosure;

FIG. 3 is a flowchart of an example method for treating a tantalum metal thin film according to some embodiments of the present disclosure;

FIG. 4 is a schematic diagram of changes of CPW resonant cavity intrinsic Q values measured by an experiment before and after cooling multiple groups of tantalum-based CPW resonant cavity samples to an extremely low temperature and recovering the multiple groups of tantalum-based CPW resonant cavity samples to normal temperature, according to some embodiments of the present disclosure; and

FIG. 5 is a structural block diagram of an example quantum computer, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms or definitions incorporated by reference. It should be noted that the terms such as “first” and “second” in this specification, the claims, and the foregoing accompanying drawings of the present disclosure are intended to distinguish between similar objects rather than describe a particular sequence or a chronological order. It is to be understood that data used in this way is exchangeable in a proper case, so that the embodiments of the present disclosure described herein can be implemented in an order different from the order shown or described herein. Moreover, the terms “include”, “have” and any other variants mean to cover the non-exclusive inclusion. For example, a process, method, system, product, or device that includes a list of steps or units is not necessarily limited to those expressly listed steps or units, but may include other steps or units not expressly listed or inherent to such a process, method, system, product, or device.

As stated above, in conventional technologies, after a tantalum metal thin film is prepared for a tantalum-based superconducting quantum device, a post-treatment process occurs. But the conventional post-treatment process has the technical problem of a limited effect on the performance of energy dissipation, as the conventional post-treatment process is similar to a post-treatment method for a thin film material in the traditional semiconductor industry. Thus, these conventional post-treatment processes having has limited, if any, positive impact on improving the performance of energy dissipation of the tantalum-based superconducting quantum device. Meanwhile, there is a certain constraint relationship between these conventional post-treatment methods and other device preparation steps. In most cases, these conventional post-treatment methods need to be strictly performed in a specific order.

Energy dissipation refers to energy dissipation (or quantum dissipation) of a quantum device in the present disclosure, which refers to energy exchange or information exchange between an object (a quantum device) and an environment in a quantum open system, resulting in loss of coherence. Researching the quantum dissipation aims to derive a classical dissipation law based on the quantum mechanics.

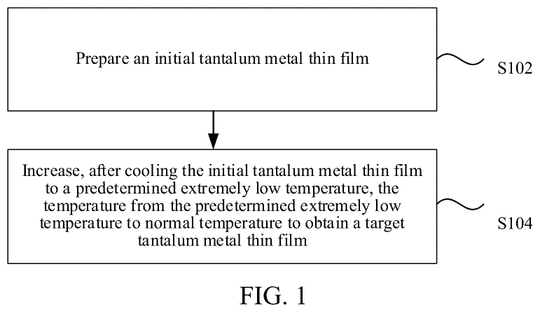

In view of the above problem, in the present disclosure, an example method for treating a tantalum metal thin film as shown in FIG. 1 is provided. FIG. 1 is a flowchart of a method for treating a tantalum metal thin film according to some embodiments of the present disclosure. It should be noted that steps shown in the flowchart in the accompanying drawings may be executed in a computer system such as a set of computer-executable instructions. Furthermore, although a logical order is shown in the flowchart, in some cases, the steps shown or described may be executed in an order different from the order here. As shown in FIG. 1, the method includes the following steps:

Step S102: An initial tantalum metal thin film is prepared. Tantalum is a metal element, which has an atomic number of 73 and a chemical symbol of Ta. A simple substance corresponding to the element is steel grey metal, which has extremely high corrosion resistance. Under either a cold condition or a hot condition, tantalum will not react with hydrochloric acid, concentrated nitric acid, and aqua regia. In addition, tantalum shows a superconducting characteristic at a low temperature. Tantalum mainly exists in tantalite and coexists with niobium. Tantalum has moderate hardness and high ductility, and can be drawn into a filament type thin foil. Its coefficient of thermal expansion is very small. Tantalum has excellent chemical properties and extremely high corrosion resistance. Tantalum can be used to manufacture an evaporator, or can be used as an electrode of an electronic tube, a rectifier, and an electrolytic capacitor. Tantalum is medically used to prepare thin sheets or filaments to sew damaged tissues. Although tantalum has extremely high corrosion resistance, the corrosion resistance is achieved by a stable tantalum pentoxide (Ta₂O₅) protective film formed on its surface.

Step S104: After the initial tantalum metal thin film is cooled to a predetermined extremely low temperature, the temperature is increased from the predetermined extremely low temperature to normal temperature to obtain a target tantalum metal thin film. That is, the process of increasing the temperature of the tantalum metal thin film from the extremely low temperature to the normal temperature assists with obtaining the tantalum metal thin film subsequently used for preparing the desired superconducting quantum device. In this way, as compared to convention post-treatment process, the embodiments of the present disclosure significantly improve upon the energy dissipation of the superconducting quantum device. Thus, the technical problem in the related technology that a post-treatment technology for the tantalum metal thin film after preparation of a tantalum metal thin film has a limited positive effect on reducing the energy dissipation of a tantalum-based superconducting quantum device is solved.

In the present disclosure, absolute zero, also referred to as “extreme minimum temperature”, is the beginning of an absolute temperature scale and is the lowest limit of temperature, which is equivalent to −273.15° C. At this temperature, thermal motions of all atoms and molecules will stop. The third law of thermodynamics defines that absolute zero cannot be achieved through a finite cooling process, so absolute zero is a minimum temperature that can only be approached but cannot be reached. Extremely low temperature refers to a low temperature that is close to the absolute zero mentioned above with respect to the absolute zero mentioned above.

In the present disclosure, normal temperature, also referred to as general temperature or room temperature, is generally defined to be 25° C. There are differences in calculated values of the normal temperature among different industries. For example, in engineering, the normal temperature is generally 20° C.; in a chemical system, a design temperature of the normal temperature is −20° C. to 200° C.; and in the pharmaceutical industry, the normal temperature refers to 10° C. to 30° C.

In some embodiments, the above-mentioned post-treatment different from the conventional post-treatment is adopted: After the tantalum metal thin film is first cooled to the extremely low temperature, the temperature is increased from the extremely low temperature to the normal temperature, so that a microstructure of the tantalum metal thin film changes, thus affecting the macroscopic performance of the tantalum metal thin film. This effectively achieves a significant decrease in energy dissipation of the tantalum metal superconducting quantum device prepared on the basis of the tantalum metal thin film obtained through the post-treatment method.

In some embodiments, the above preparation of the initial tantalum metal thin film may be carried out using an ordinary preparation method, such as sputtering. Sputtering is a phenomenon where charged particles bombard a surface of a solid, and the atoms or molecules of the surface of the solid acquire a part of energy carried by the incident particles, and are sputtered. The most commonly used sputtering method is generally ion sputtering. Ions are prone to acceleration or deflection in an electromagnetic field. The charged particles are generally ions. This type of sputtering is referred to as ion sputtering. A process of coating by sputtering is referred to as a sputtering coating process, in which, charged ions are used to obtain sufficient energy under the action of an electromagnetic field to bombard a solid (target) substance. Atoms sputtered from a surface of the target substance are shot towards a substrate at a certain amount of kinetic energy, thus forming a thin film on the substrate.

In some embodiments, the above predetermined extremely low temperature may be a low temperature close to absolute zero. For example, the predetermined extremely low temperature may be a temperature within a temperature range. For example, the predetermined extremely low temperature may be within the temperature range from 0 mK to 120 K, or from 0 mK to 77 K. Optionally, the predetermined extremely low temperature may be 5 mK, 10 mK, 15 mK, 20 mK, 10 K, 20 K, 30 K, 60 K, 70 K, and the like. Preferably, the predetermined extremely low temperature is 10 mK.

In some embodiments, after the initial tantalum metal thin film is cooled to the predetermined extremely low temperature, the temperature is increased from the predetermined extremely low temperature to the normal temperature to obtain the target tantalum metal thin film. During which, the cooling process and the temperature rise process may be controlled by a predetermined control method. For example, it can be controlled that after the initial tantalum metal thin film is cooled to the predetermined extremely low temperature within a first predetermined duration, the temperature is increased from the predetermined extremely low temperature to normal temperature within a second predetermined duration to obtain the target tantalum metal thin film. It should be noted that the above first predetermined duration may be flexibly determined on the basis of a need of preparing the target tantalum metal thin film or a need of preparing a target quantum device. The above second predetermined duration may also be flexibly determined on the basis of the need of preparing the target tantalum metal thin film or the need of preparing the target quantum device. Optionally, the first predetermined duration may be counted in days and in some other examples counted in hours, and the second predetermined duration may be counted in days and in some other examples counted in hours.

In some embodiments, a sequential order of the process of obtaining the target tantalum metal thin film by cooling the initial tantalum metal thin film to the predetermined extremely low temperature and then increasing the temperature from the predetermined extremely low temperature to the normal temperature and the process of preparing the quantum device does not need to be strictly restrained as there is no interdependence between the two processes, which can effectively avoid the protection costs in the preparation process. For example, it is possible that after the target tantalum metal thin film is obtained by cooling the initial tantalum metal thin film to the predetermined extremely low temperature and then increasing the temperature from the predetermined extremely low temperature to the normal temperature, the tantalum-based superconducting quantum device is prepared on the basis of the target tantalum metal thin film. That is, after a post-treatment method of performing cooling to a predetermined extremely low temperature and then slowly increasing the temperature to normal temperature is used to treat the initial tantalum metal thin film to obtain the target tantalum metal thin film, the tantalum metal superconducting quantum device is then prepared on the basis of the target tantalum metal thin film.

In some embodiments, when the target tantalum metal thin film is obtained by cooling the initial tantalum metal thin film to the predetermined extremely low temperature and then increasing the temperature from the predetermined extremely low temperature to the normal temperature, the process of preparing the target tantalum metal thin film can also be a process of preparing a tantalum metal base layer in a quantum device. For example, a tantalum metal base layer used for preparing a tantalum-based superconducting quantum devices can be first prepared on the basis of the initial tantalum metal thin film; and after the tantalum metal base layer is cooled to the predetermined extremely low temperature, the temperature is increased from the predetermined extremely low temperature to the normal temperature to obtain a target tantalum metal base layer formed by the target tantalum metal thin film. It should be noted that after the tantalum metal base layer of the tantalum-based superconducting quantum device is prepared, before the post-treatment of performing cooling to the predetermined extremely low temperature and then increasing the temperature to the normal temperature is used, other superconducting material layers of tantalum-based superconducting quantum device can be prepared first, or the above-mentioned post-treatment operations can be directly carried out without the preparation of other superconducting material layers.

In some embodiments, the above-mentioned tantalum-based superconducting quantum device may be a variety of superconducting quantum devices. For example, the above-mentioned tantalum-based superconducting quantum device may be a Fluxonium quantum bit, a co-planar waveguide (CPW), or the like. For quantum bit, in the classical mechanical system, a state of a bit is unique. In quantum mechanics, the quantum bit is allowed to be superposition of two states at the same moment, which is a fundamental property of quantum computation. Physically speaking, the quantum bit is a quantum state. Therefore, the quantum bit has a property of the quantum state. Due to the unique quantum property of the quantum state, the quantum bit has many characteristics that are different from the classical bit, which is one of the essential characteristics of the quantum information science. Fluxonium is a type of superconducting quantum bit, which is formed by connecting a Josephson junction in parallel to an inductor and a capacitor.

A quantum logic can be completed by a set of single-quantum-bit and double-quantum-bit gate, where the double-quantum bit logic gate takes two quantum bits as inputs. Usually, a first quantum bit is a control bit, and a second quantum bit is a target bit. Common examples are controlled non gates (CNOT gates) and controlled phase gates (CZ gates or CPHASE gates). A universal set of single-quantum-bit and double-quantum-bit gate is sufficient to implement any quantum logic, and meanwhile, each single-quantum-bit and double-quantum-bit gate is reversible, meaning that if an output state is given, an input state can be uniquely determined.

A central conductor belt is made on one surface of a dielectric substrate, and conductor planes are made on two sides closely adjacent to the central conductor belt, so that the CPW is formed, which is also referred to as a coplanar microstrip transmission line. The CPW propagates TEM waves without a cutoff frequency. Due to the fact that the central conductor and the conductor plane are located in the same plane, it is very convenient to mount components in parallel on the CPW. The CPW can be used to make a monolithic microwave integrated circuit (MIMIC) with a transmission line and components on the same side. The CPW, as a high-performance and easily processed microwave planar transmission line, plays an increasingly important role in the MIMIC circuit. Especially in a millimeter wave frequency band, the CPW has an unparalleled performance advantage compared to a microstrip line. Compared with a conventional microstrip transmission line, the CPW has the advantages of easy fabrication, easy realization of series and parallel connection of passive and active devices in microwave circuits (without perforation on substrates), easy improvement of a circuit density, and the like. Compared with a symmetric CPW, an asymmetric CPW has higher flexibility when connected to devices at both ends. The CPW is a quasi two-dimensional structure composed of conductors (superconductors), and can be used to form a microwave device.

For example, the Fluxonium quantum bit is formed by connecting a Josephson junction in parallel to an inductor and a capacitor. Components included, such as the Josephson junction, the inductor, and the capacitor, can all be prepared on the basis of the target tantalum metal thin film prepared by the above method. It should be noted that the above target tantalum metal thin film is not limited to preparation of a Fluxonium quantum bit, but is also applicable to preparation of other tantalum-based quantum bits or related devices, which will not be listed here.

Based on the above described embodiments, the present disclosure provides an optional implementation, which will be explained below.

As mentioned above, a superconducting material with low energy dissipation is a foundation for achieving long-coherence and high-performance superconducting quantum bits and related superconducting quantum devices. Metal tantalum exhibits better potential in energy dissipation compared to commonly used superconducting materials (for example, metal aluminum). In the optional implementations of the present disclosure, a method for improving the performance of a superconducting quantum device prepared on the basis of a tantalum (Ta) metal thin film is provided. This simple and effective method can significantly reduce the energy dissipation of the tantalum-based superconducting quantum device, which provides a foundation for preparation of long-coherence superconducting quantum bits (namely, high-performance superconducting quantum bits) and related superconducting quantum circuits using tantalum metal thin films.

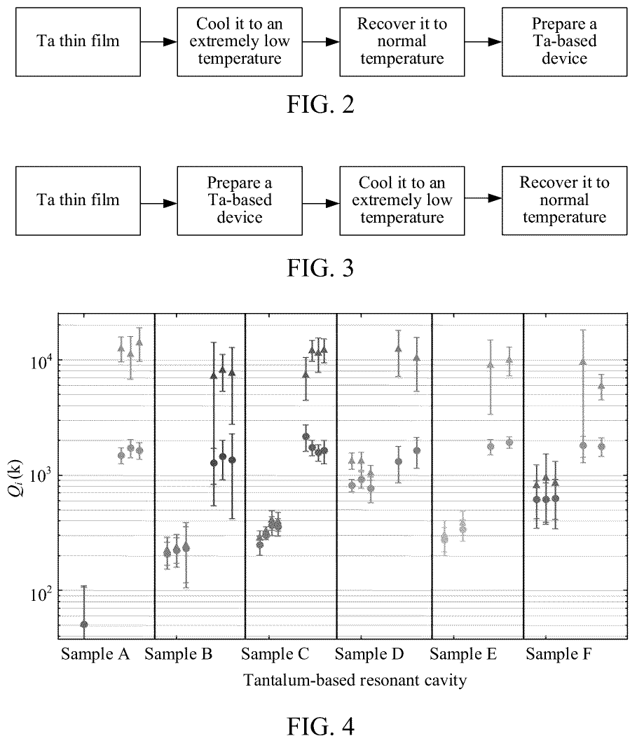

FIG. 2 is a flowchart of a method for treating a tantalum metal thin film according to some embodiments of the present disclosure. As shown in FIG. 2, the method includes the following steps: after a tantalum metal thin film is prepared using a certain method (for example, a sputtering method), the tantalum metal thin film is first cooled to an extremely low temperature (about 10 mK) and is then slowly recovered to normal temperature, followed by preparation of a tantalum-based superconducting quantum device.

FIG. 3 is a flowchart of another method for treating a tantalum metal thin film according to some embodiments of the present disclosure. As shown in FIG. 3, the method includes the following steps: after a tantalum metal thin film is prepared using a certain method (for example, a sputtering method), a corresponding superconducting quantum device is first prepared (only a part corresponding to a tantalum metal base layer may be prepared without preparing all components); and this part is then cooled to an extremely low temperature (about 10 mK) and is then slowly recovered to normal temperature.

Through the above method, the performance of the tantalum-based superconducting quantum device in energy dissipation can be significantly improved after adding the treatment of performing cooling to the extremely low temperature and recovery to the normal temperature.

The following takes a CPW resonant cavity as an example. The performance of energy dissipation of the tantalum-based superconducting quantum device obtained using the treatment of performing cooling to the extremely low temperature and recovery to the normal temperature of the present disclosure will be explained on the basis of measurement results.

FIG. 4 is a schematic diagram of changes of CPW resonant cavity intrinsic Q values measured by an experiment before and after cooling multiple groups of tantalum-based CPW resonant cavity samples to an extremely low temperature and recovering the multiple groups of tantalum-based CPW resonant cavity samples to normal temperature, according to some embodiments of the present disclosure. As shown in FIG. 4, the multiple groups of tantalum-based CPW resonant cavity samples are Samples A to F. After the treatment of performing cooling to the extremely low temperature and recovery to the normal temperature, key indicators (intrinsic Q values) that characterize the energy dissipation characteristics of the samples are significantly improved.

Quality factor (also referred to as Q factor representing by e.g., an intrinsic Q value) is a dimensionless parameter in physics and engineering, a physical quantity that represents a damping property of an oscillator. The quality factor can also represent a magnitude of a resonance frequency of the oscillator relative to a bandwidth. A high Q factor indicates a low rate of energy loss of the oscillator and a longer duration of vibration. For example, a single pendulum moving in air has a higher Q factor, while a single pendulum moving in oil has a lower Q factor. Oscillators with high Q factors generally have smaller damping. In the present disclosure, the Q factor is used as a quantitative indicator for characterizing a loss rate of a resonant cavity. For example, a resonant cavity formed by a CPW is used to characterize an energy loss rate of the resonant cavity. For example, if an electromagnetic field is completely concentrated in the CPW cavity, without radiation loss, the CPW has a high quality factor.

Each sample has multiple CPW resonant cavity components. The solid symbol (e.g., the solid circular symbol, the solid triangular symbol) represents an average value of the intrinsic Q values of the multiple components on the sample, and the error symbol with a span range on the intrinsic value axis (Qi) represents a standard deviation. That is, the higher the span range of the error symbol is, the higher the standard deviation is. The circular and triangular symbols respectively represent the intrinsic Q values at low and high measurement power. Different grids correspond to different samples (for example, sample A, sample B, sample C, and the like in the figure). For the same sample, the left hand side and right hand side legends represent measurement results of the same sample before and after the treatment of performing cooling to the extremely low temperature and recovery to the normal temperature. According to experimental data, it can be seen that after the treatment of performing cooling to the extremely low temperature and recovery to the normal temperature, the average intrinsic Q value of the same sample has been significantly increased at either low measurement power or high measurement power.

For example, in FIG. 4, for the same sample (sample A), there are three pieces of measurement data at low measurement power and high measurement power respectively, which are results of repeated measurements for three times. The results indicate that the treatment method for performing cooling to the extremely low temperature and recovery to the normal temperature has a lasting effect on the improvement of the performance of the tantalum-based superconducting quantum device, and the effect will not decrease due to multiple extreme measurement conditions or long-term placement.

It should be noted that in this optional implementation, as shown in FIG. 2 and FIG. 3 above, the treatment steps of performing cooling to the extremely low temperature and recovery to the normal temperature can be executed before or after other preparation steps of tantalum-based devices. This will not affect the improvement on the performance of the tantalum metal thin film by this treatment. In addition, a thickness of the tantalum metal thin film will be independent of other parameters. For example, in FIG. 4, sample D is a tantalum metal thin film with a thickness of 100 nm; samples A to C are tantalum metal thin films with a thickness of 200 nm; sample E is a tantalum metal thin film with a thickness of 300 nm; and sample F is a tantalum metal thin film with a thickness of 400 nm. The above methods for post-treating the tantalum metal thin films all can effectively improve the performance of the tantalum metal thin films.

Compared to the method for post-treating a metal thin film in conventional technologies, the method for post-treating the tantalum metal thin film adopted in this optional implementation has the following characteristics:

Compared to the commonly used conventional methods for post-treating the metal thin film in the related technology, which basically inherit methods for treating a thin film material in the traditional semiconductor industry, including chemical cleaning, ion milling, and high-temperature annealing, the method of performing cooling to the extremely low temperature and recovery to the normal temperature in this optional implementation is not a common treatment method.

The conventional processing method has a certain constraint relationship between the preparation step of the tantalum metal thin film and other preparation steps of superconducting quantum devices. In most cases, these preparation steps need to be strictly implemented in a specific order. In some embodiments of the present disclosure, the treatment method of performing cooling to the extremely low temperature and recovery to the normal temperature in this optional implementation does not have the above constraint, and has good compatibility with various preparation processes and high flexibility in process integration.

While the conventional processing method has a limited, if any, effect on improving the performance of energy dissipation of the tantalum-based superconducting quantum device, the disclosed treatment method of performing cooling to the extremely low temperature and recovery to the normal temperature in this optional implementation has a significant improvement effect on the performance of multiple groups of tantalum-based samples with different parameters (thin film thicknesses).

Moreover, the efficacy of the conventional processing method gradually deteriorates over time. For example, surface cleaning related treatment may result in degradation of the efficacy due to chemical reactions between the surface and air or further gradual contamination of the surface. The disclosed treatment method of performing cooling to the extremely low temperature and recovery to the normal temperature has a lasting effect, and the effect will not decrease due to multiple extreme measurement conditions or long-term placement.

The disclosed method for post-treating the tantalum metal thin film has the following characteristics, and can achieve the following beneficial effects:
Can significantly improve the performance of energy dissipation of the tantalum-based superconducting quantum device by adding the treatment steps of performing cooling to the extremely low temperature and recovery to the normal temperature.
Can be flexibly performed before or after other preparation process steps of the superconducting quantum device, which can also effectively improve the performance of a final device.
Can have an improvement effect on the tantalum metal thin films with various different parameters (thin film thicknesses), and has relatively wide applicability.
Has a lasting effect on improving the performance of the tantalum-based superconducting quantum device, and the effect will not decrease due to multiple extreme measurement conditions or long-term placement.

According to the embodiments of the present disclosure, a quantum device is further provided. The quantum device is a tantalum-based superconducting quantum device. The tantalum-based superconducting quantum device includes a tantalum metal base layer. The tantalum metal base layer includes a target tantalum metal thin film. The target tantalum metal thin film is obtained by using any method for treating a tantalum metal thin film described above.

According to the embodiments of the present disclosure, a quantum chip is further provided, which includes any one of the above-mentioned quantum devices. The so-called quantum chip is obtained by integrating a quantum circuit onto a substrate to bear a function of processing quantum information.

According to the embodiments of the present disclosure, a quantum memory is further provided, which includes any one of the above-mentioned quantum devices.

The embodiments of the present disclosure can further provide a quantum computer. The quantum computer may be any quantum computer device in a quantum computer group. The quantum computer device can be a superconducting quantum computer.

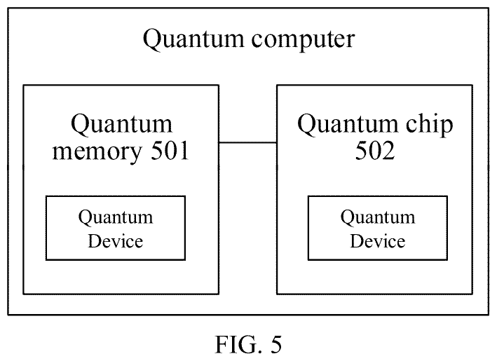

Optionally, FIG. 5 is a structural block diagram of a quantum computer according to some embodiments of the present disclosure. As shown in FIG. 5, the quantum computer may include: a quantum memory 501 and a quantum chip 502.

A quantum device included in the quantum memory 501 is a tantalum-based superconducting quantum device. A quantum device included in the quantum chip 502 is a tantalum-based superconducting quantum device. The tantalum-based superconducting quantum device includes a tantalum metal base layer. The tantalum metal base layer includes a target tantalum metal thin film. The target tantalum metal thin film is obtained by using any method for treating a tantalum metal thin film described above.

It is appreciated that the structures shown in FIG. 5 are only illustrative, and FIG. 5 does not constitute a limitation on the above structures. For example, the quantum computer may further include more or fewer components than those shown in FIG. 5, or have a configuration different from that shown in FIG. 5.

It is appreciated that all or some of the steps in the various methods of the foregoing embodiments may be completed by instructing hardware related to a terminal device through corresponding preparation devices and programs. The programs may be stored in a computer-readable storage medium. The storage medium may include: a flash drive, a Read-Only Memory (ROM), a Random Access Memory (RAM), a magnetic disk, an optical disc, or the like.

In the several embodiments provided in the present disclosure, it should be understood that the disclosed technical content may be implemented in other manners. The foregoing described apparatus embodiments are merely examples. For example, the unit division is merely logical function division and there may be other division manners in practical implementations. For example, multiple units or components may be combined or integrated into another system, or some features may be omitted or not performed. In addition, the coupling, direct coupling, or communication connection between the displayed or discussed components may be the indirect coupling or communication connection by means of some interfaces, units, or modules, and may be electrical or of other forms.

The units described as separate parts may or may not be physically separated, and parts displayed as units may or may not be physical units, that is, may be located in one position, or may be distributed on multiple network units. Some or all of the units may be selected according to actual needs to achieve the objectives of the solutions of the embodiments.

In addition, functional units in the embodiments of the present disclosure may be integrated into one processing unit, or each of the units may be physically separated, or two or more units may be integrated into one unit. The integrated unit may be implemented in the form of hardware, or may be implemented in a form of a software functional unit.

When the integrated unit is implemented in the form of a software functional unit and sold or used as an independent product, the integrated unit may be stored in a computer-readable storage medium. Based on such an understanding, the technical solutions of the present disclosure essentially, or the part contributing to the prior art, or all or some of the technical solutions may be presented in the form of a software product. The computer software product is stored in a storage medium, and includes several instructions for instructing a computer device (which may be a personal computer, a server, a network device, or the like) to perform all or some of the steps of the methods of the various embodiments of the present disclosure. The foregoing storage medium includes: various media that can store program codes, such as a USB flash drive, a read-only memory (ROM), a random access memory (RAM), a removable hard disk, a magnetic disk, and an optical disc.

The foregoing descriptions are preferable implementations of the present disclosure only. It is noted that a person of ordinary skill in the art may make some improvements and modifications without departing from the principle of the present disclosure and the improvements and modifications shall fall within the protection scope of the present disclosure.

What is claimed is:

1. A method for treating a tantalum metal thin film, comprising:
preparing an initial tantalum metal thin film; and
increasing, after cooling the initial tantalum metal thin film to a predetermined extremely low temperature, the temperature from the predetermined extremely low temperature to normal temperature to obtain a target tantalum metal thin film.

2. The method according to claim 1, wherein the predetermined extremely low temperature is located within the following temperature range: 0 mK to 77 K.

3. The method according to claim 1, wherein the predetermined extremely low temperature is located within the following temperature range: 0 mK to 120 K.

4. The method according to claim 2, wherein the predetermined extremely low temperature is 10 mK.

5. The method according to claim 1, wherein the normal temperature is a temperature greater than zero degrees Celsius.

6. The method according to claim 1, wherein increasing, after cooling the initial tantalum metal thin film to the predetermined extremely low temperature, the temperature from the predetermined extremely low temperature to the normal temperature to obtain the target tantalum metal thin film comprises:
increasing, after cooling the initial tantalum metal thin film to the predetermined extremely low temperature within a first predetermined duration, the temperature from the predetermined extremely low temperature to the normal temperature within a second predetermined duration to obtain the target tantalum metal thin film.

7. The method according to claim 6, wherein the first predetermined duration is counted in days, and the second predetermined duration is counted in days.

8. The method according to claim 6, wherein the first predetermined duration is counted in hours, and the second predetermined duration is counted in hours.

9. The method according to claim 1, wherein after increasing the temperature from the predetermined extremely low temperature to the normal temperature to obtain a target tantalum metal thin film, the method further comprises:
preparing a tantalum-based superconducting quantum device on the basis of the target tantalum metal thin film.

10. The method according to claim 1, wherein increasing the temperature from the predetermined extremely low temperature to the normal temperature to obtain the target tantalum metal thin film comprises:
preparing, on the basis of the initial tantalum metal thin film, a tantalum metal base layer used for preparing a tantalum-based superconducting quantum device; and
increasing, after cooling the tantalum metal base layer to the predetermined extremely low temperature, the temperature from the predetermined extremely low temperature to the normal temperature to obtain a target tantalum metal base layer formed by the target tantalum metal thin film.

11. The method according to claim 9, wherein the tantalum-based superconducting quantum device is Fluxonium quantum bit.

12. A quantum device, wherein the quantum device is a tantalum-based superconducting quantum device comprising a tantalum metal base layer; wherein the tantalum metal base layer comprises a target tantalum metal thin film that is obtained by using the method for treating a tantalum metal thin film according to claim 1.

13. A quantum chip, comprising the quantum device according to claim 12.

14. A quantum memory, comprising the quantum device according to claim 12.

15. A quantum computer, comprising a quantum chip and a quantum memory, wherein the quantum chip or the quantum memory comprises the quantum device according to claim 12.

16. The method according to claim 3, wherein the predetermined extremely low temperature is 10 mK.

17. The method according to claim 10, wherein the tantalum-based superconducting quantum device is Fluxonium quantum bit.
